(19) United States
(12) Patent Application Publication
(10) Pub. No.: US 2025/0143054 A1
(43) Pub. Date: May 1, 2025

(54) DISPLAY PANEL, MANUFACTURING METHOD THEREOF, AND DISPLAY DEVICE

(71) Applicant: TCL CHINA STAR OPTOELECTRONICS TECHNOLOGY CO., LTD., Shenzhen (CN)

(72) Inventor: Jinhui GONG, Shenzhen (CN)

(21) Appl. No.: 17/800,161

(22) PCT Filed: Aug. 12, 2022
(86) PCT No.: PCT/CN2022/112051

§ 371 Date: Dec. 30, 2024

(30) Foreign Application Priority Data
Jul. 29, 2022 (CN) 202210907194.8

(51) Int. Cl. H10H 29/49; H10H 29/01

(52) U.S. Cl. CPC H10H 29/49; H10H 29/0364

(57) ABSTRACT

The present application provides a display panel, a manufacturing method thereof, and a display device. By defining a first height difference between a first terminal part and a second terminal part of a first bonding terminal, so that after attaching a protective layer, a suspended area is defined between the protective layer and the first terminal part, so that when preparing a surrounding wire, a metal conductive thin film is disconnected in the suspended area, thus the surrounding wire will not be lifted when the protective layer is removed, so as to alleviate a problem of peeling of a surrounding wire of existing display panels when removing a protective layer.

### TECHNICAL FIELD

The present application relates to a field of display technology, and specifically to a display panel, a manufacturing method thereof, and a display device.

### BACKGROUND

A double-sided process is one of processes to realize seamless splicing display of mini light-emitting diode (mini-LED) products and micro light-emitting diode (micro-LED) products. The double-sided process is a process that a light-emitting layer is disposed on a front surface of a display panel and an outer lead bonding (OLB) area is defined on a back surface of the display panel; then, a connection of front connecting terminals and back connecting terminals can be realized by preparing a plurality of surrounding wires on the front surface, a side surface, and the back surface of the display panel, respectively. A connection of the front connecting terminals and the light-emitting layer is realized through bottom wires, and a connection of the back connecting terminals and a driving signal source is also realized through the bottom wires and a connection of the back wires; finally, it can be realized that driving signals generated from the back surface can drive the light-emitting layer located on the front surface to emit light through the surrounding wires.

When preparing the surrounding wires, a preparing process is to form a whole layer of a surrounding conductive film by sputtering first, and then form the surrounding wires by using a laser engraving process. In addition, in order to protect the display panel, a protective layer is usually attached on the front surface and the back surface of the display panel before preparing the surrounding wires, and the protective layer will be stripped after finishing a preparation of the surrounding wires. However, since the whole layer of the surrounding conductive film formed by sputtering will also cover the protective layer, a peeling phenomenon is easy to occur to the surrounding wires located on connecting terminals when peeling the protective layer, resulting in a broken circuit or poor bonding.

### SUMMARY

### Technical Problem

The present application provides a display panel, a manufacturing method thereof, and a display device, so as to alleviate a technical problem of peeling of surrounding wires of existing display panels when removing a protective layer.

### SOLUTIONS TO THE PROBLEM

### Technical Solutions

In order to solve the above problem, technical solutions provided in the present application are as follows:

An embodiment of the present application provides a display panel, which includes a display area and a bonding area located on a side of the display area, wherein the display panel further includes:
a substrate, the substrate including a first surface, a second surface disposed opposite to the first surface, and a side surface connecting the first surface and the second surface;
bonding terminals, disposed in the bonding area, the bonding terminals including a first bonding terminal disposed on the first surface and a second bonding terminal disposed on the second surface; and
a surrounding wire, disposed on the side surface and connected to the first bonding terminal and the second bonding terminal;
wherein the first bonding terminal includes a first terminal part and a second terminal part, and a first height difference is defined between the first terminal part and the second terminal part; a part of the first surface in contact with the first terminal part is defined as a reference surface, a height of a surface of the first terminal part away from the substrate relative to the reference surface is less than a height of a surface of the second terminal part away from the substrate relative to the reference surface.

In the display panel provided by an embodiment of the present application, the first surface is defined with at least one first groove, an end of the first groove facing the side surface is open, and the first terminal part is located in the first groove.

In the display panel provided by an embodiment of the present application, the first surface is defined with a plurality of first grooves arranged at intervals and in sequence.

In the display panel provided by an embodiment of the present application, a thickness of the first terminal part is less than or equal to a depth of the first groove.

In the display panel provided by an embodiment of the present application, a second groove is defined in the first groove, an end of the second groove facing the side surface is open, and the first terminal part is further located in the second groove.

In the display panel provided by an embodiment of the present application, a part of the surrounding wire covers the first terminal part, and a thickness of the part of the surrounding wire is less than or equal to the first height difference.

In the display panel provided by an embodiment of the present application, the second bonding terminal includes a third terminal part and a fourth terminal part, and a second height difference is defined between the third terminal part and the fourth terminal part, a height of a surface of the third terminal part away from the substrate relative to the reference surface is less than a height of a surface of the fourth terminal part away from the substrate relative to the reference surface.

In the display panel provided by an embodiment of the present application, the second surface is defined with a third groove, an end of the third groove facing the side surface is open, and the third terminal part is located in the third groove.

An embodiment of the present application provides a manufacturing method of a display panel, which includes:
providing a substrate, wherein the substrate includes a first surface, a second surface disposed opposite to the first surface, and a side surface connecting the first surface and the second surface, and the substrate is divided into a display area and a bonding area;
preparing bonding terminals on the substrate corresponding to the bonding area, including preparing a first bonding terminal on the first surface and preparing a second bonding terminal on the second surface; wherein the first bonding terminal includes a first terminal part and a second terminal part, and a first height difference is defined between the first terminal part and the second terminal part; a part of the first surface in contact with the first terminal part is defined as a reference surface, a height of a surface of the first terminal part away from the substrate relative to the reference surface is less than a height of a surface of the second terminal part away from the substrate relative to the reference surface;
attaching a first protective layer, including attaching the first protective layer on a side of the first surface away from the second surface, wherein the first protective layer covers the display area and extends from the display area to the bonding area, and the first protective layer covers the second terminal part and extends along a direction away from the display area, so as to define a suspended area between the first protective layer and the first terminal part;
preparing a surrounding wire, wherein the surrounding wire covers the side surface and is connected to the first bonding terminal and the second bonding terminal; and
removing the first protective layer.

In the manufacturing method of the display panel provided by an embodiment of the present application, the step of preparing the first bonding terminal on the first surface further includes:
defining at least one first groove on the first surface of the substrate, an end of the first groove facing the side surface is open; and
preparing the first bonding terminal on the first surface, wherein the first terminal part is located in the at least one first groove, and the second terminal part is located on the first surface outside the at least one first groove, so as to define the first height difference between the first terminal part and the second terminal part.

In the manufacturing method of the display panel provided by an embodiment of the present application, the step of defining the at least one first groove on the first surface of the substrate further includes:
defining a plurality of first grooves arranged at intervals and in sequence on the first surface of the substrate by a laser engraving process or a wet etching process.

In the manufacturing method of the display panel provided by an embodiment of the present application, the step of preparing the surrounding wire further includes:
depositing a whole layer of a metal conductive thin film on the first protective layer and the side surface of the substrate, the metal conductive thin film being disconnected in the suspended area; and
engraving the metal conductive thin film on the side surface of the substrate by a laser engraving process, so as to form the surrounding wire.

An embodiment of the present application further provides a display device, which includes a plurality of mutually spliced display panels, each of the display panels including a display area and a bonding area located on a side of the display area, wherein each of the display panels further includes:
a substrate, the substrate including a first surface, a second surface disposed opposite to the first surface, and a side surface connecting the first surface and the second surface;
bonding terminals, disposed in the bonding area, the bonding terminals including a first bonding terminal disposed on the first surface and a second bonding terminal disposed on the second surface; and
a surrounding wire, disposed on the side surface and connected to the first bonding terminal and the second bonding terminal;
wherein the first bonding terminal includes a first terminal part and a second terminal part, and a first height difference is defined between the first terminal part and the second terminal part; a part of the first surface in contact with the first terminal part is defined as a reference surface, a height of a surface of the first terminal part away from the substrate relative to the reference surface is less than a height of a surface of the second terminal part away from the substrate relative to the reference surface.

In the display device provided by an embodiment of the present application, the first surface is further defined with at least one first groove, an end of the first groove facing the side surface is open, and the first terminal part is located in the first groove.

In the display device provided by an embodiment of the present application, the first surface is further defined with a plurality of first grooves arranged at intervals and in sequence.

In the display device provided by an embodiment of the present application, a thickness of the first terminal part is less than or equal to a depth of the first groove.

In the display device provided by an embodiment of the present application, a second groove is defined in the first groove, an end of the second groove facing the side surface is open, and the first terminal part is further located in the third groove.

In the display device provided by an embodiment of the present application, a part of the surrounding wire covers the first terminal part, and a thickness of the part of the surrounding wire is less than or equal to the first height difference.

In the display device provided by an embodiment of the present application, the second bonding terminal includes a third terminal part and a fourth terminal part, and a second height difference is defined between the third terminal part and the fourth terminal part, a height of a surface of the third terminal part away from the substrate relative to the reference surface is less than a height of a surface of the fourth terminal part away from the substrate relative to the reference surface.

In the display device provided by an embodiment of the present application, the second surface is defined with a third groove, an end of the third groove facing the side surface is open, and the third terminal part is located in the second groove.

### BENEFICIAL EFFECTS OF THE INVENTION

### Beneficial Effects

In the display panel, the manufacturing method thereof, and the display device provided by the present application, by defining the first height difference between the first terminal part and the second terminal part of the first bonding terminal, so that after attaching the first protective layer, due to an existence of the first height difference, the suspended area is defined between the first protective layer and the first terminal part, so that when preparing the surrounding wire, the metal conductive thin film is disconnected in the suspended area, then the surrounding wire will not be lifted when removing the first protective layer, thereby solving a problem of the peeling of the surrounding wires of the existing display panels when removing the protective layer.

### BRIEF DESCRIPTION OF THE DRAWINGS

### Description of Drawings

In order to more clearly explain embodiments or technical solutions in the prior art, the following will briefly introduce drawings that need to be used in description of the embodiments or the prior art. It is obvious that the drawings in the following description are only some embodiments of the present application. For those skilled in the art, other drawings can be obtained from these drawings without paying creative labor.

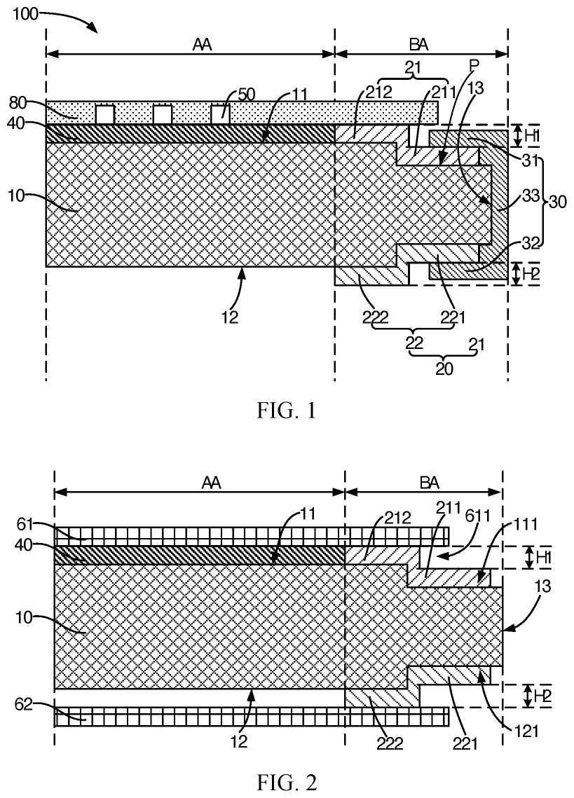

FIG. 1 is a first cross-sectional schematic structural diagram of a display panel provided by an embodiment of the present application.

FIG. 2 is a cross-sectional schematic structural diagram of the display panel before removing a protective layer provided by the embodiment of the present application.

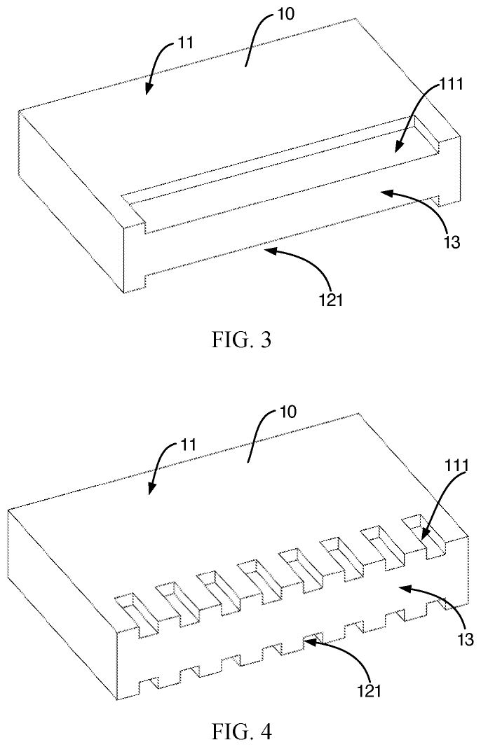

FIG. 3 is a first schematic structural diagram of a substrate provided by the embodiment of the present application.

FIG. 4 is a second schematic structural diagram of the substrate provided by the embodiment of the present application.

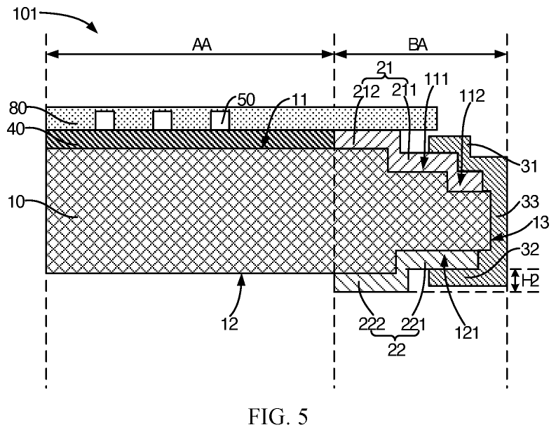

FIG. 5 is a second cross-sectional schematic structural diagram of the display panel provided by an embodiment of the present application.

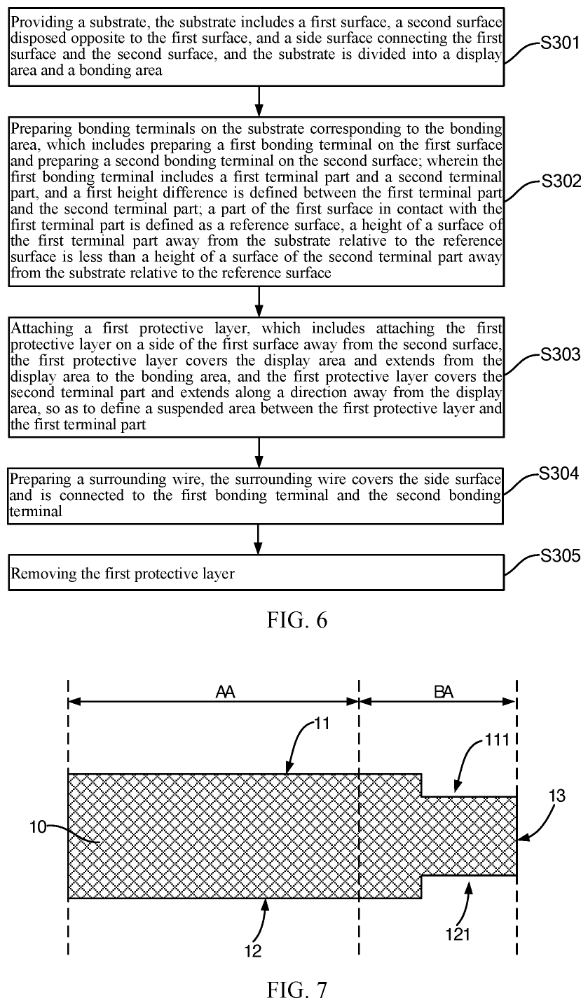

FIG. 6 is a schematic flow diagram of a manufacturing method of the display panel provided by an embodiment of the present application.

FIG. 7 is a cross-sectional schematic structural diagram after defining a first groove and a third groove on the substrate provided by the embodiment of the present application.

FIG. 8 is a cross-sectional schematic structural diagram after preparing a driving circuit and bonding terminals on the substrate of FIG. 7.

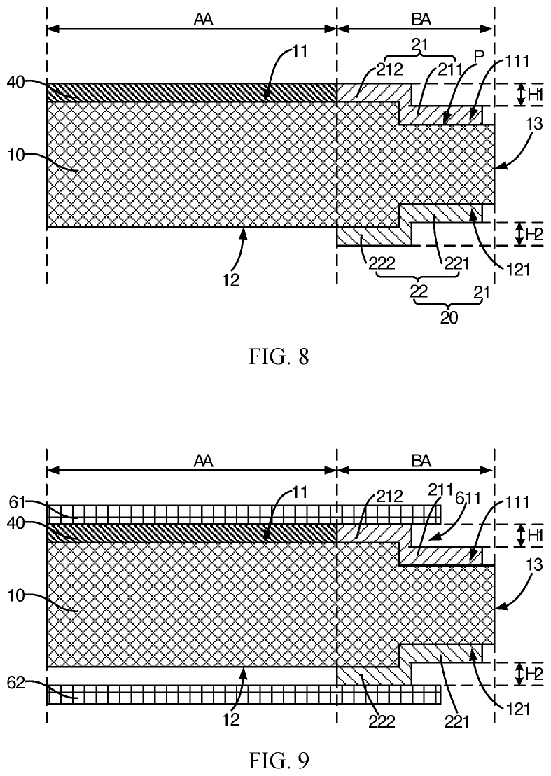

FIG. 9 is a cross-sectional schematic structural diagram after attaching the protective layer on a basis of FIG. 8.

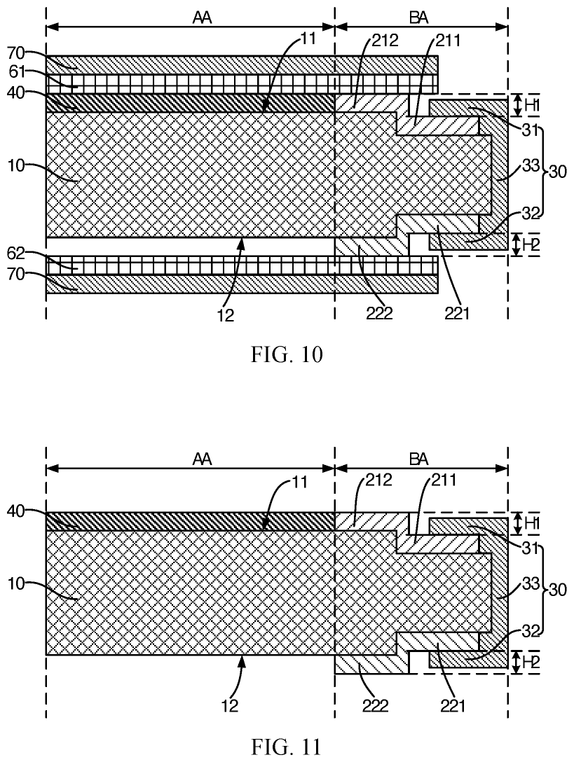

FIG. 10 is a cross-sectional schematic structural diagram after depositing a metal conductive thin film on a basis of FIG. 9.

FIG. 11 is a cross-sectional schematic structural diagram after removing the protective layer on a basis of FIG. 10.

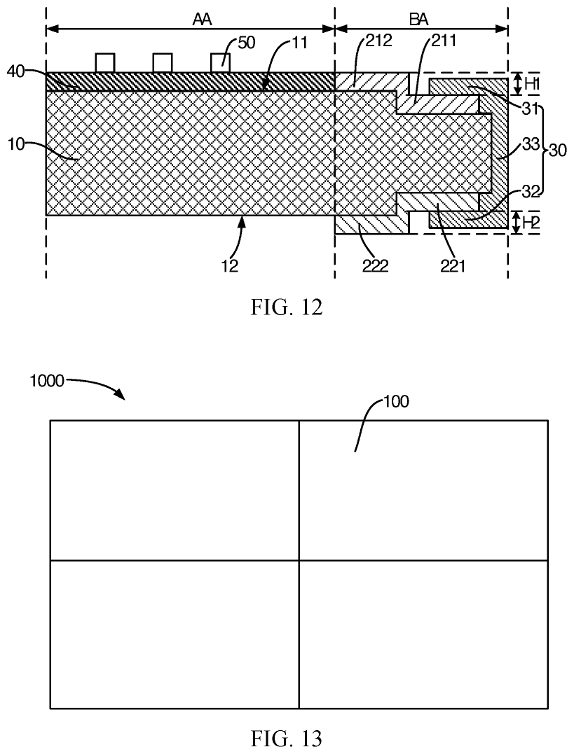

FIG. 12 is a cross-sectional schematic structural diagram after preparing light-emitting units on a basis of FIG. 11.

FIG. 13 is a top view schematic structural diagram of the display device provided by an embodiment of the present application.

### DETAILED DESCRIPTION

### EMBODIMENTS OF THE INVENTION

Following description of embodiments refers to additional illustrations to illustrate specific embodiments that the present application can be implemented. Direction terms mentioned in the present application, such as [up], [down], [front], [back], [left], [right], [inside], [outside], [side], etc., are only directions of reference to additional schemas. Therefore, directional languages used are to explain and understand the present application, not to limit the present application. In the drawings, units with similar structures are represented by a same label. In the drawings, thicknesses of some layers and areas are exaggerated for clear understanding and easy description. That is, a size and a thickness of each of the components shown in the drawings are arbitrarily shown, but the present application is not limited to this.

Please refer to FIG. 1 to FIG. 4. FIG. 1 is a first sectional and schematic structural diagram of a display panel provided by an embodiment of the present application, FIG. 2 is a sectional and schematic structural diagram of the display panel before removing a protective layer provided by the embodiment of the present application, FIG. 3 is a first schematic structural diagram of a substrate provided by the embodiment of the present application, and FIG. 4 is a second schematic structural diagram of the substrate provided by the embodiment of the present application. The display panel 100 includes a display area AA and a bonding area BA located on a side of the display area AA; the display area AA is used for displaying pixels, and the bonding area BA is used for disposing bonding terminals. Specifically, the display panel 100 includes the substrate 10, and the bonding terminals 20 and a surrounding wire 30 disposed on the substrate 10. Certainly, the display panel 100 also includes a driving circuit 40 and light-emitting units 50 located on the substrate 10, wherein the driving circuit 40 and the light-emitting units 50 are located in the display area AA, and the bonding terminals 20 and the surrounding wire 30 are located in the bonding area BA. The bonding terminals 20 are electrically connected to the driving circuit 40 to provide driving signals to the driving circuit 40, so as to drive the light-emitting units 50 to emit light, thereby realizing display of the pixels of the display panel 100.

Specifically, the substrate 10 includes a first surface 11, a second surface 12 disposed opposite to the first surface 11, and a side surface 13 connecting the first surface 11 and the second surface 12. A material of the substrate 10 can be a rigid material, such as glass, transparent resin, etc., or a flexible material, such as polyimide, polycarbonate, polyethersulfone, polyethylene terephthalate, polyethylene naphthalate, polyaryl compounds, or glass fiber reinforced plastics, etc., and the material of the substrate 10 is not limited by the present application. Wherein the first surface 11 of the substrate 10 corresponds to a front surface of the display panel 100, that is, a surface on which the display panel 100 displays the pixels, and the driving circuit 40 and the light-emitting units 50 are disposed on the first surface 11. The second surface 12 of the substrate 10 corresponds to a back surface of the display panel 100. The side surface 13 of the substrate 10 connects the first surface 11 and the second surface 12, and is close to the bonding area BA.

The bonding terminals 20 are disposed in the bonding area BA, and the bonding terminals 20 include a first bonding terminal 21 disposed on the first surface 11 and a second bonding terminal 22 disposed on the second surface 12.

The first bonding terminal 21 includes a first terminal part 211 and a second terminal part 212. A first height difference H1 is defined between the first terminal part 211 and the second terminal part 212, a part of the first surface 11 in contact with the first terminal part 211 is defined as a reference surface P, a height of a surface of the first terminal 211 away from the substrate 10 relative to the reference surface P is less than a height of a surface of the second terminal 212 away from the substrate 10 relative to the reference surface P.

The second bonding terminal 22 includes a third terminal part 221 and a fourth terminal part 222. A second height difference H2 is defined between the third terminal part 221 and the fourth terminal part 222. A height of a surface of the third terminal part 221 away from the substrate 10 relative to the reference surface P is less than a height of a surface of the fourth terminal part 222 away from the substrate 10 relative to the reference surface P.

The surrounding wire 30 is disposed on the side surface 13 and connected to the first bonding terminal 21 and the second bonding terminal 22. Wherein a part of the surrounding wire 30 covers the first terminal part 211, and a thickness of the surrounding wire 30 covering on the first terminal part 211 is less than or equal to the first height difference H1; the part of the surrounding wire 30 covers the third terminal part 221, and a thickness of the surrounding wire 30 covering on the third terminal part 221 is less than or equal to the second height difference H2.

Specifically, the surrounding wire 30 includes a first conductive part 31, a second conductive part 32, and a third conductive part 33 connected to the first conductive part 31 and the second conductive part 32. The first conductive part 31 covers the first terminal part 211 and is electrically connected to the first terminal part 211. A thickness of the first conductive part 31 is less than or equal to the first height difference H1, and the thickness of the first conductive part 31 ranges from 100 nm to 10 μm.

The second conductive part 32 covers the third terminal part 221 and is electrically connected to the third terminal part 221. A thickness of the second conductive part 32 is less than or equal to the second height difference H2, and the thickness of the second conductive part 32 ranges from 100 nm to 10 μm. The third conductive part 33 covers the side surface 13 of the substrate 10. Wherein the thickness of the first conductive part 31 and the thickness of the second conductive part 32 both refer to a thickness along a direction perpendicular to the first surface 11.

Alternatively, an end of the first terminal part 211 away from the display area AA is uneven with the side surface 13 of the substrate 10, and the end of the first terminal part 211 shrinks toward the display area AA compared with the side surface 13 of the substrate 10, so as to expose a part of the first surface 11. Similarly, an end of the third terminal part 221 away from the display area AA is also uneven with the side surface 13 of the substrate 10, and the end of the third terminal part 221 also shrinks toward the display area AA compared with the side surface 13 of the substrate 10, so as to expose a part of the second surface 12. Thus, while covering the side surface 13 of the substrate 10, the third conductive part 33 also covers the part of the first surface 11 and the part of the second surface 12, which can increase a contacting area between the third conductive part 33 and the substrate 10, thereby improving a bonding force between the third conductive part 33 and the substrate 10.

Defining the first height difference H1 and the second height difference H2 will be described in detail below.

Specifically, in the bonding area BA, the first surface 11 is defined with a first groove 111, and an end of the first groove 111 facing the side surface 13 is open. The first terminal part 211 is located in the first groove 111, and the second terminal part 212 is located on the first surface 11 outside the reference surface P, that is, the second terminal part 212 is located on the first surface 11 outside the first groove 111.

Wherein the first terminal part 211 and the second terminal part 212 are integrally arranged, and a thickness of the first terminal part 211 is same as a thickness of the second terminal part 212. Thus, since the first terminal part 211 is located in the first groove 111, and the second terminal part 212 is located outside the first groove 111, so that the first terminal part 211 and the second terminal part 212 are not located on a same horizontal plane, so as to define the first height difference H1 between the first terminal part 211 and the second terminal part 212.

Similarly, the second surface 12 is defined with a third groove 121, and an end of the third groove 121 facing the side surface 13 is open. The third terminal part 221 is located in the third groove 121, and the fourth terminal part 222 is located on the second surface 12 outside the third groove 121.

Wherein the third terminal part 221 and the fourth terminal part 222 are integrally arranged, and a thickness of the third terminal part 221 is same as a thickness of the fourth terminal part 222. Thus, since the third terminal part 221 is located in the third groove 121, and the fourth terminal part 222 is located outside the third groove 121, so that the third terminal part 221 and the fourth terminal part 222 are not located on a same horizontal plane, so as to define the second height difference H2 between the third terminal part 221 and the fourth terminal part 222. Wherein alternatively, the second height difference H2 is equal to the first height difference H1.

Certainly, in some embodiments, the thickness of the first terminal part 211 can also be less than the thickness of the second terminal part 212, thus, when a required first height difference H1 is defined, the first groove 111 with a small depth can be defined to reduce process difficulty, and at a same time, fracture of the substrate 10 caused by defining a deeper groove on the substrate 10 can be avoided.

Similarly, in some embodiments, the thickness of the third terminal part 221 can also be less than the thickness of the fourth terminal part 222, thus, when a required second height difference H2 is defined, the third groove 121 with a smaller depth can be defined to reduce process difficulty, and at a same time, fracture of the substrate 10 caused by defining a deeper groove on the substrate 10 can be avoided.

It can be understood that before forming the surrounding wire 30, a protective layer is needed to be attached to protect the driving circuit 40 located on the substrate 10, and the protective layer covers the display area AA and a part of the bonding area BA. Wherein the protective layer includes a first protective layer 61 and a second protective layer 62. Specifically, as shown in FIG. 2, the first protective layer 61 is attached on a side of the first surface 11 away from the second surface 12, and the second protective layer 62 is attached on a side of the second surface 12 away from the first surface 11. Due to an existence of the first height difference H1 and the second height difference H2, a suspended area 611 is defined between the first protective layer 61 and the first terminal part 211, and a suspended area is also defined between the second protective layer 62 and the third terminal part 221. In this way, when forming the surrounding wire 30, a deposited metal conductive thin film is disconnected in the suspended area, and then when the first protective layer 61 and the second protective layer 62 are removed, the metal conductive thin film located on the first terminal part 211 and the third terminal part 221 will not be lifted, which can solve a problem of peeling of a surrounding wire of existing display panels when the protective layer is removed.

Next, structures of the first groove 111 and the third groove 121 will be described in detail.

In an embodiment, as shown in FIG. 3, the first groove 111 is continuously disposed, that is, in the bonding area BA, the first surface 11 is defined with a whole strip of the first groove 111, and the whole strip of the first groove 111 corresponds to an area where the first terminal part 211 needs to be disposed, which can make a process of defining the first groove 111 relatively simple and reduce process difficulty. Alternatively, a width of the first groove 111 ranges from 30 μm to 200 μm, and a depth of the first groove 111 ranges from 10 μm to 100 μm. Wherein the width of the first groove 111 refers to a distance that the first groove 111 extends along a direction perpendicular to the side surface 13, and the depth of the first groove 111 refers to a distance that the first groove 111 extends along a direction perpendicular to the first surface 11.

Alternatively, the first terminal part 211 is located in the first groove 111, and the thickness of the first terminal part 211 is less than or equal to the depth of the first groove 111, so as to increase the first height difference H1. For example, the thickness of the first terminal 211 ranges from 100 nm to 10 μm.

Similarly, in one embodiment, the third groove 121 is also continuously disposed, that is, in the bonding area BA, the second surface 12 is defined with a whole strip of the third groove 121, and the whole strip of the third groove 121 corresponds to an area where the third terminal part 221 needs to be disposed, which can make a process of defining the third groove 121 relatively simple and reduce the process difficulty. Alternatively, a width of the third groove 121 ranges from 30 μm to 200 μm, and a depth of the third groove 121 ranges from 10 μm to 500 μm. Wherein a definition of the width and the depth of the third groove 121 can refer to a definition of the width and the depth of the first groove 111, which will not be repeated here.

Alternatively, the third terminal part 221 is located in the third groove 121, and the thickness of the third terminal part 221 is less than or equal to the depth of the third groove 121, so as to increase the second height difference H2. For example, the thickness of the third terminal part 221 ranges from 100 nm to 10 μm.

In another embodiment, as shown in FIG. 4, the first groove 111 is discontinuous. Specifically, the first surface 11 is defined with a plurality of first grooves 111 arranged at intervals and in sequence, an end of each of the first grooves 111 facing the side surface 13 is open, and the first terminal part 211 is located in the first groove 111. In this way, after attaching the first protective layer 61, due to blocking of the substrate 10 between two adjacent ones of the first grooves 111, the first protective layer 61 will not contact the first terminal part 211 located in the first groove 111 under an action of gravity, so that a more stable suspended area 611 can be defined between the first protective layer 61 and the first terminal part 211.

Alternatively, a length of the first groove 111 ranges from 20 μm to 100 μm, the width of the first groove 111 ranges from 30 μm to 200 μm, the depth of the first groove 111 ranges from 10 μm to 100 μm, and a spacing distance between the two adjacent ones of the first grooves 111 ranges from 30 μm to 100 μm, so as to match a design of the first terminal 211. The thickness of the first terminal 211 is less than or equal to the depth of the first groove 111. Wherein the length of the first groove 111 refers to an extension distance of each of the first grooves 111 along a spacing direction of the first groove 111.

Similarly, in an embodiment, the third groove 121 is also discontinuous. Specifically, the second surface 12 is defined with a plurality of third grooves 121 arranged at intervals and in sequence, an end of each of the third grooves 121 facing the side surface 13 is open, and the third terminal part 221 is located in the third groove 121. In this way, after attaching the second protective layer 62, due to the blocking of the substrate 10 between two adjacent ones of the third grooves 121, the second protective layer 62 will not contact the third terminal part 221 located in the third groove 121 under the action of gravity, so that a more stable suspended area can be defined between the second protective layer 62 and the third terminal part 221.

Alternatively, a length of the third groove 121 ranges from 20 μμm to 100 μm, a width of the third groove 121 ranges from 30 μm to 200 μm, a depth of the third groove 121 ranges from 10 μm to 100 μm, and a spacing distance between the two adjacent ones of the third grooves 121 ranges from 30 μm to 100 μm, so as to match a design of the third terminal part 221. The thickness of the third terminal part 221 is less than or equal to the depth of the third groove 121. Wherein the length of the third groove 121 refers to an extension distance of each of the third grooves 121 along a spacing direction of the third groove 121.

It can be understood that in an embodiment, please continue to refer to FIG. 1, the display panel 100 further includes an encapsulation layer 80 disposed on the driving circuit 40 and the light-emitting units 50, so as to protect the driving circuit 40 and the light-emitting units 50. Alternatively, the light-emitting units 50 includes mini light-emitting diodes (mini-LEDs) or micro light-emitting diodes (micro-LEDs).

In an embodiment, please refer to FIG. 1 to FIG. 5. FIG. 5 is a second sectional and schematic structural diagram of a display panel provided by the embodiment of the present application. Difference from the above embodiment is that, in the display panel 101 of the embodiment, a second groove 112 is defined in the first groove 111, an end of the second groove 112 facing the side surface 13 is open, and the first terminal part 211 is also located in the second groove 112, so that a stepped height difference is defined between the second terminal part 212 and the first terminal part 211.

When the first protective layer 61 is attached on the side of the first surface 11 away from the second surface 12, due to an existence of the stepped height difference defined on the first surface 11, a larger suspended area will be defined between the first protective layer 61 and the first terminal part 211, so that when forming the surrounding wire 30, it is easier for the deposited metal conductive thin film to disconnect in the suspended area. Certainly, the third groove 121 can also adopt a stepped design similar to the first groove 111, which will not be repeated here. Please refer to the above embodiments for other descriptions, and it will not be repeated here.

In an embodiment, please refer to FIG. 1 to FIG. 4, and FIG. 6 to FIG. 12. FIG. 6 is a schematic flow diagram of a manufacturing method of the display panel provided by the embodiment of the present application, FIG. 7 is a sectional and schematic structural diagram after defining the first groove and the third groove on the substrate provided by the embodiment of the present application, FIG. 8 is a sectional and schematic structural diagram after preparing the driving circuit and the bonding terminals on the substrate shown in FIG. 7, FIG. 9 is a sectional and schematic structural diagram after attaching the protective layer on a basis of FIG. 8, FIG. 10 is a sectional and schematic structural diagram after depositing the metal conductive thin film on a basis of FIG. 9, FIG. 11 is a sectional and schematic structural diagram after removing the protective layer on a basis of FIG. 10, and FIG. 12 is a sectional and schematic structural diagram after preparing the light-emitting units on a basis of FIG. 11. The manufacturing method of the display panel includes following steps:

S301: providing the substrate 10, the substrate 10 includes the first surface 11, the second surface 12 disposed opposite to the first surface 11, and the side surface 13 connecting the first surface 11 and the second surface 12, and the substrate 10 is divided into the display area AA and the bonding area BA.

Specifically, as shown in FIG. 7, the substrate 10 is provided, and in the bonding area BA, the first groove 111 is defined on the first surface 11 of the substrate 10 by a laser engraving process or a wet etching process; and the third groove 121 is defined on the second surface 12 of the substrate 10 by a same one of the laser engraving process or the wet etching process. Wherein alternatively, using the laser engraving process or the wet etching process to define the plurality of first grooves 111 arranged at intervals and in sequence on the first surface 11 of the substrate 10, and define the plurality of third grooves 121 arranged at intervals and in sequence on the second surface 12 of the substrate 10, as shown in FIG. 4.

S302: preparing the bonding terminals 20 on the substrate 10 corresponding to the bonding area BA, which includes preparing the first bonding terminal 21 on the first surface 11 and preparing the second bonding terminal 22 on the second surface 12; wherein the first bonding terminal 21 includes the first terminal part 211 and the second terminal part 212, and the first height difference H1 is defined between the first terminal part 211 and the second terminal part 212; the part of the first surface 11 in contact with the first terminal part 211 is defined as the reference surface P, the height of the surface of the first terminal part 211 away from the substrate 10 relative to the reference surface P is less than the height of the surface of the second terminal part 212 away from the substrate 10 relative to the reference surface P.

Specifically, depositing the metal conductive thin film on the first surface 11 and the second surface 12 of the substrate 10 by a physical vapor deposition (PVD) method, an ion plating process, or a magnetron sputtering process, and patterning the deposited metal conductive thin film by a yellow light process, so as to form the driving circuit 40 and the first bonding terminal 21 located on the first surface 11, and form the second bonding terminal 22 located on the second surface 12, as shown in FIG. 8. Wherein the driving circuit 40 is located in the display area AA, the first bonding terminal 21 and the second bonding terminal 22 are located in the bonding area BA, and the first bonding terminal 21 is electrically connected to the driving circuit 40.

Further, the first bonding terminal 21 includes the first terminal part 211 and the second terminal part 212, the first terminal part 211 is located in the first groove 111, and the second terminal part 212 is located on the first surface 11 outside the first groove 111, so that the first height difference H1 is defined between the first terminal part 211 and the second terminal part 212. Specifically, the part of the first surface 11 in contact with the first terminal part 211 is defined as the reference surface P, the height of the surface of the first terminal part 211 away from the substrate 10 relative to the reference surface P is less than the height of the surface of the second terminal part 212 away from the substrate 10 relative to the reference surface P.

The second bonding terminal 22 includes the third terminal part 221 and the fourth terminal part 222, the third terminal part 221 is located in the third groove 121, and the fourth terminal part 222 is located on the second surface 12 outside the third groove 121, so that the second height difference H2 is defined between the third terminal part 221 and the fourth terminal part 222. Specifically, the height of the surface of the third terminal part 221 away from the substrate 10 relative to the reference surface P is less than the height of the surface of the fourth terminal part 222 away from the substrate 10 relative to the reference surface P.

S303: attaching the first protective layer, which includes attaching the first protective layer 61 on the side of the first surface 11 away from the second surface 12, wherein the first protective layer 61 covers the display area AA and extends from the display area AA to the bonding area BA, and the first protective layer 61 covers the second terminal part 212 and extends along a direction away from the display area AA, so as to define the suspended area 611 between the first protective layer 61 and the first terminal part 211, as shown in FIG. 9.

The second protective layer 62 is attached on the side of the second surface 12 away from the first surface 11, the second protective layer 62 covers the display area AA and extends from the display area AA to the bonding area BA, and the second protective layer 62 covers the fourth terminal part 222 and extends along the direction away from the display area AA, so as to define the suspended area between the second protective layer 62 and the third terminal part 221. Wherein along the direction perpendicular to the side surface 13 of the substrate 10, a length of the first protective layer 61 beyond the second terminal part 212 is less than a length of the first terminal part 211, and a length of the second protective layer 62 beyond the fourth terminal part 222 is less than a length of the third terminal part 221.

Alternatively, the first protective layer 61 and the second protective layer 62 both can be polyimide films or polyethylene terephthalate (PET) films, which has special performances such as high strength, high toughness, wear resistance, high temperature resistance, and corrosion resistance, etc., so as to protect the driving circuit 40.

S304: preparing the surrounding wire 30, wherein the surrounding wire 30 covers the side surface 13 and is connected to the first bonding terminal 21 and the second bonding terminal 22.

Specifically, as shown in FIG. 10, a whole layer of the metal conductive thin film 70 is deposited on the substrate 10 by the physical vapor deposition method, the ion plating process, or the magnetron sputtering process, and the metal conductive thin film 70 covers the first protective layer 61, the second protective layer 62, the first terminal part 211, the second terminal part 212, and the side surface 13 of the substrate 10. Moreover, due to the existence of the first height difference H1, the metal conductive thin film 70 is disconnected in the suspended area 611 defined between the first protective layer 61 and the first terminal part 211, and due to the existence of the second height difference H2, the metal conductive thin film 70 is disconnected in the suspended area defined between the second protective layer 62 and the third terminal part 221.

Further, the metal conductive thin film 70 located in an area outside an area where the first protective layer 61 and the second protective layer 62 are located is engraved by the laser engraving process, so as to form the surrounding wire 30 connecting the first bonding terminal 21 and the second bonding terminal 22, and the surrounding wire 30 is not in contact with the metal conductive thin film 70 located on a surface of the first protective layer 61 and on a surface of the second protective layer 62.

The surrounding wire 30 includes the first conductive part 31, the second conductive part 32, and the third conductive part 33 connected to the first conductive part 31 and the second conductive part 32. The first conductive part 31 covers the first terminal part 211 and is electrically connected to the first terminal part 211. The thickness of the first conductive part 31 is less than or equal to the first height difference H1, and the thickness of the first conductive part 31 ranges from 100 nm to 10 μm. The second conductive part 32 covers the third terminal part 221 and is electrically connected to the third terminal part 221. The thickness of the second conductive part 32 is less than or equal to the first height difference H1, and the thickness of the second conductive part 32 ranges from 100 nm to 10 μm. The third conductive part 33 covers the side surface 13 of the substrate 10.

S305: removing the first protective layer.

Specifically, as shown in FIG. 11, after forming the surrounding wire 30, the first protective layer 61 and the second protective layer 62 are removed. Since the metal conductive thin film 70 located on the first protective layer 61 is disconnected with the surrounding wire 30, so that the first conductive part 31 located on the first terminal part 211 will not be lifted when the first protective layer 61 is removed; similarly, since the metal conductive thin film 70 located on the second protective layer 62 is disconnected with the surrounding wire 30, the second conductive part 32 located on the third terminal part 221 will not be lifted when the second protective layer 62 is removed. Thus, when the first protective layer 61 and the second protective layer 62 are removed, it will not lead to the peeling of the surrounding wire 30.

Further, as shown in FIG. 12, after removing the first protective layer 61 and the second protective layer 62, the light-emitting units 50 are prepared on the driving circuit 40, wherein the light-emitting units 50 includes the mini-LEDs or the micro-LEDs, etc. After preparing the light-emitting units 50, the encapsulation layer 80 is prepared on the light-emitting units 50 to protect the light-emitting units 50 and the driving circuit 40, so as to form the display panel 100 shown in FIG. 1.

In an embodiment, please refer to FIG. 1 to FIG. 13, FIG. 13 is a top view schematic structural diagram of a display device provided by an embodiment of the present application. The display device 1000 includes the display panel of one of the above embodiments. Alternatively, the display device 1000 is a spliced display screen, taking the display panel 100 as an example, then the display device 1000 includes a plurality of the display panels 100, and the plurality of the display panels 100 are mutually spliced. Since the display panel 100 of the present application adopts a double-sided process, a splicing seam does not exist in the display device 1000 formed after splicing of the plurality of the display panels 100.

According to the above embodiments:

The present application provides the display panel, the manufacturing method thereof, and the display device. By defining the first height difference between the first terminal part and the second terminal part of the first bonding terminal, so that after attaching the protective layer, due to the existence of the first height difference, the suspended area is defined between the protective layer and the first terminal part, so that when preparing the surrounding wire, the metal conductive thin film is disconnected in the suspended area; furthermore, the surrounding wire will not be lifted when removing the protective layer, which can solve a problem of the peeling of surrounding wires of existing display panels when removing the protective layer.

In the above embodiments, the description of each of the embodiments has its own emphasis. For a part not detailed in one embodiment, please refer to relevant description of other embodiments.

The above describes the embodiments of the present application in detail. In this paper, specific examples are used to explain principles and implementation methods of the present application. The description of the above embodiments is only used to help understand a technical scheme and core ideas of the present application; those skilled in the art should understand that they can still modify technical solutions recorded in the above-mentioned embodiments, or equivalent replace some of the technical features; and these modifications or replacements do not make an essence of the corresponding technical solutions separate from a scope of the technical solutions of the embodiments of the present application.

What is claimed is:

1. A display panel, comprising a display area and a bonding area located on a side of the display area, wherein the display panel further comprises:
a substrate, the substrate comprising a first surface, a second surface disposed opposite to the first surface, and a side surface connecting the first surface and the second surface;
bonding terminals, disposed in the bonding area, the bonding terminals comprising a first bonding terminal disposed on the first surface and a second bonding terminal disposed on the second surface; and
a surrounding wire, disposed on the side surface and connected to the first bonding terminal and the second bonding terminal;
wherein the first bonding terminal comprises a first terminal part and a second terminal part, and a first height difference is defined between the first terminal part and the second terminal part; a part of the first surface in contact with the first terminal part is defined as a reference surface, a height of a surface of the first terminal part away from the substrate relative to the reference surface is less than a height of a surface of the second terminal part away from the substrate relative to the reference surface.

2. The display panel according to claim 1, wherein the first surface is defined with at least one first groove, an end of the first groove facing the side surface is open, and the first terminal part is located in the first groove.

3. The display panel according to claim 2, wherein the first surface is further defined with a plurality of first grooves arranged at intervals and in sequence.

4. The display panel according to claim 2, wherein a thickness of the first terminal part is less than or equal to a depth of the first groove.

5. The display panel according to claim 2, wherein a second groove is defined in the first groove, an end of the second groove facing the side surface is open, and the first terminal part is further located in the second groove.

6. The display panel according to claim 1, wherein a part of the surrounding wire covers the first terminal part, and a thickness of the part of the surrounding wire is less than or equal to the first height difference.

7. The display panel according to claim 1, wherein the second bonding terminal comprises a third terminal part and a fourth terminal part, and a second height difference is defined between the third terminal part and the fourth terminal part, a height of a surface of the third terminal part away from the substrate relative to the reference surface is less than a height of a surface of the fourth terminal part away from the substrate relative to the reference surface.

8. The display panel according to claim 7, wherein the second surface is defined with a third groove, an end of the third groove facing the side surface is open, and the third terminal part is located in the third groove.

9. A manufacturing method of a display panel, comprising:
providing a substrate, wherein the substrate comprises a first surface, a second surface disposed opposite to the first surface, and a side surface connecting the first surface and the second surface, and the substrate is divided into a display area and a bonding area;
preparing bonding terminals on the substrate corresponding to the bonding area, comprising preparing a first bonding terminal on the first surface and preparing a second bonding terminal on the second surface; wherein the first bonding terminal comprises a first terminal part and a second terminal part, and a first height difference is defined between the first terminal part and the second terminal part; a part of the first surface in contact with the first terminal part is defined as a reference surface, a height of a surface of the first terminal part away from the substrate relative to the reference surface is less than a height of a surface of the second terminal part away from the substrate relative to the reference surface;
attaching a first protective layer, comprising attaching the first protective layer on a side of the first surface away from the second surface, wherein the first protective layer covers the display area and extends from the display area to the bonding area, and the first protective layer covers the second terminal part and extends along a direction away from the display area, so as to define a suspended area between the first protective layer and the first terminal part;
preparing a surrounding wire, wherein the surrounding wire covers the side surface and is connected to the first bonding terminal and the second bonding terminal; and
removing the first protective layer.

10. The manufacturing method of the display panel according to claim 9, wherein the step of preparing the first bonding terminal on the first surface further comprises:
defining at least one first groove on the first surface of the substrate, an end of the first groove facing the side surface is open; and
preparing the first bonding terminal on the first surface, wherein the first terminal part is located in the at least one first groove, and the second terminal part is located on the first surface outside the at least one first groove, so as to define the first height difference between the first terminal part and the second terminal part.

11. The manufacturing method of the display panel according to claim 10, wherein the step of defining the at least one first groove on the first surface of the substrate further comprises:
defining a plurality of first grooves arranged at intervals and in sequence on the first surface of the substrate by a laser engraving process or a wet etching process.

12. The manufacturing method of the display panel according to claim 9, wherein the step of preparing the surrounding wire further comprises:
depositing a whole layer of a metal conductive thin film on the first protective layer and the side surface of the substrate, the metal conductive thin film being disconnected in the suspended area; and
engraving the metal conductive thin film on the side surface of the substrate by a laser engraving process, so as to form the surrounding wire.

13. A display device, comprising a plurality of mutually spliced display panels, each of the display panels comprising a display area and a bonding area located on a side of the display area, wherein each of the display panels further comprises:
a substrate, the substrate comprising a first surface, a second surface disposed opposite to the first surface, and a side surface connecting the first surface and the second surface;
bonding terminals, disposed in the bonding area, the bonding terminals comprising a first bonding terminal disposed on the first surface and a second bonding terminal disposed on the second surface; and
a surrounding wire, disposed on the side surface and connected to the first bonding terminal and the second bonding terminal;
wherein the first bonding terminal comprises a first terminal part and a second terminal part, and a first height difference is defined between the first terminal part and the second terminal part; a part of the first surface in contact with the first terminal part is defined as a reference surface, a height of a surface of the first terminal part away from the substrate relative to the reference surface is less than a height of a surface of the second terminal part away from the substrate relative to the reference surface.

14. The display device according to claim 13, wherein the first surface is further defined with at least one first groove, an end of the first groove facing the side surface is open, and the first terminal part is located in the first groove.

15. The display device according to claim 14, wherein the first surface is further defined with a plurality of first grooves arranged at intervals and in sequence.

16. The display device according to claim 14, wherein a thickness of the first terminal part is less than or equal to a depth of the first groove.

17. The display device according to claim 14, wherein a second groove is defined in the first groove, an end of the second groove facing the side surface is open, and the first terminal part is further located in the third groove.

18. The display device according to claim 13, wherein a part of the surrounding wire covers the first terminal part, and a thickness of the part of the surrounding wire is less than or equal to the first height difference.

19. The display device according to claim 13, wherein the second bonding terminal comprises a third terminal part and a fourth terminal part, and a second height difference is defined between the third terminal part and the fourth terminal part; a height of a surface of the third terminal part away from the substrate relative to the reference surface is less than a height of a surface of the fourth terminal part away from the substrate relative to the reference surface.

20. The display device according to claim 19, wherein the second surface is defined with a third groove, an end of the third groove facing the side surface is open, and the third terminal part is located in the second groove.
